(19) United States
(12) Patent Application Publication
(10) Pub. No.: US 2022/0341870 A1
(43) Pub. Date: Oct. 27, 2022

(54) SENSING ELECTRODE

(71) Applicant: METAL INDUSTRIES RESEARCH & DEVELOPMENT CENTRE, Kaohsiung City (TW)

(72) Inventors: Chih-Sheng Chen, Kaohsiung City (TW); Chia-Lin Chen, Kaohsiung City (TW); Shun-Min Wang, Penghu County (TW)

(21) Appl. No.: 17/237,133

(22) Filed: Apr. 22, 2021

(51) Int. Cl. G01N 27/413; G01N 27/30

(52) U.S. Cl. CPC G01N 27/413; G01N 27/301; H05K 3/00

(57) ABSTRACT

A sensing electrode includes a first electrode assembly, a second electrode assembly and a sealing component. The first electrode assembly includes an inner tubular body and a reference electrode component installed in the inner tubular body. The second electrode assembly includes an outer tubular body and a working electrode component installed in the outer tubular body. The first electrode assembly is installed in the outer tubular body. The sealing component is located between the inner and outer tubular bodies and provided to inhibit infiltration of an etching solution into the outer tubular body and leakage of an electrolyte from the inner tubular body. Thus, the sensing electrode has a better stability and service life.

### FIELD OF THE INVENTION

This invention generally relates to a sensing electrode, and more particularly to an ORP (oxidation reduction potential) electrode.

### BACKGROUND OF THE INVENTION

PCB (printed circuit board) fabrication involves many wet processes, e.g. etching and washing. If an etching solution used in etching process is the mixture of sulfuric acid (H₂SO₄) and hydrogen peroxide (H₂O₂), H₂O₂ concentration is a critical factor in the etching process and insufficient control of H₂O₂ concentration may cause uneven etching. The H₂O₂ concentration can be indirectly determined based on the measured ORP level of H₂O₂ so instant monitoring of the ORP level of H₂O₂ is helpful to control the H₂O₂ concentration during the etching process and enhance stability of etching performance.

ORP electrode made of one piece may have no risk of electrode corrosion, however, measurement error may arise because it is not easy to replace damaged or deteriorated electrode component in the ORP electrode. In contrast, it is easy to replace damaged or deteriorated electrode component or add new electrolyte into an ORP electrode not made of one piece, but infiltration of etching solution may cause a reduced service life of the ORP electrode.

### SUMMARY

One aspect of the present invention provides a sensing electrode including a first electrode assembly, a second electrode assembly, a first sealing component and a lid. The first electrode assembly includes an inner tubular body configured to accommodate an electrolyte, a reference electrode component installed in the inner tubular body and an ionic conductive component disposed through and protruding from a sensing end of the inner tubular body. The second electrode assembly includes an outer tubular body and a working electrode component installed in the outer tubular body, an exposed end of the working electrode component is exposed on a sensing end of the outer tubular body. The first electrode assembly is installed in the outer tubular body. The first sealing component is located between the sensing ends of the inner tubular body and the outer tubular body, the ionic conductive component is inserted into the first sealing component and visible from a first through hole located on the sensing end of the outer tubular body. The lid is provided to cover a conductive end of the inner tubular body.

The first sealing component of the present invention is located between the inner and outer tubular bodies to prevent an etching solution from infiltrating into the outer tubular body so the reference electrode component will not contact the etching solution and not be damaged by the etching solution to cause measurement error. Furthermore, the first sealing component also can inhibit electrolyte leakage to increase stability, accuracy and service life of the sensing electrode.

### DESCRIPTION OF THE DRAWINGS

FIG. 1 is a cross-sectional view diagram illustrating a sensing electrode in accordance with a first embodiment of the present invention.

FIG. 2 is a cross-sectional view diagram illustrating a sensing electrode in accordance with a second embodiment of the present invention.

### DETAILED DESCRIPTION OF THE INVENTION

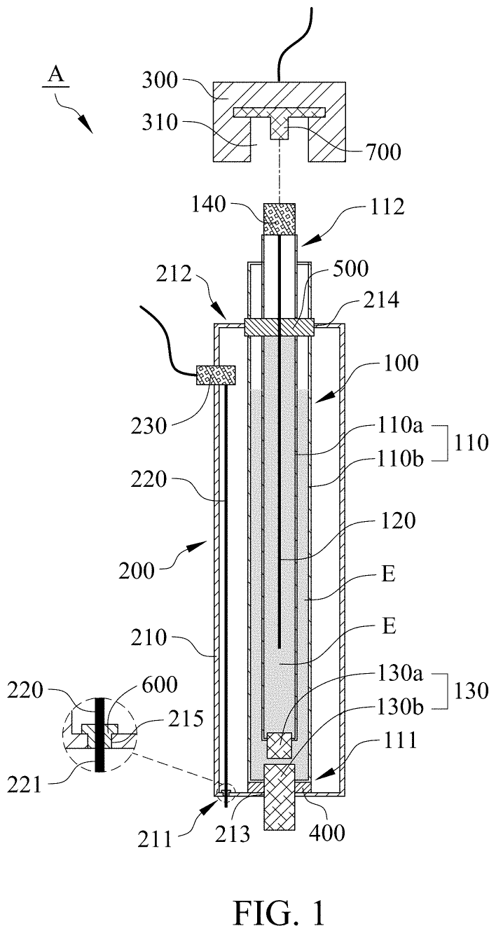

With reference to FIG. 1, a sensing electrode A disclosed in the present invention is provided for ORP measurement. For example, the sensing electrode A is installed in chemical micro-etching tank of printed circuit board factory to continuously monitor oxidative capacity of etchant which is a mixture of sulfuric acid (H₂SO₄) and hydrogen peroxide (H₂O₂). Variation of H₂O₂ concentration is detectable through the measured oxidative capacity so it is possible to adjust the etching process instantly. The sensing electrode A of the present invention can be used to measure ORP level of other analytes. With reference to FIG. 1, the sensing electrode A of a first embodiment of the present invention includes a first electrode assembly 100 that includes an inner tubular body 110, a reference electrode component 120 and an ionic conductive component 130. The inner tubular body 110 is provided for accommodating an electrolyte E, and it's both ends are defined as a sensing end 111 and conductive end 112, respectively. The reference electrode component 120 is installed in the inner tubular body 110 and may be silver/silver chloride (Ag/AgCl) electrode, saturated calomel electrode or standard hydrogen electrode. The ionic conductive component 130 is disposed through the inner tubular body 110 and protrudes from the sensing end 111.

Preferably, the ionic conductive component 130 is made of a porous ceramic material, and more preferably, the ionic conductive component 130 is made of a porous silicon oxide or a porous metal oxide. The porous metal oxide may be unary metal oxide, binary metal oxide or multinary metal oxide including at least one metal material selected from the group consisting of platinum (Pt), gold (Au), palladium (Pd), silver (Ag), iridium (Ir), titanium (Ti), ruthenium (Ru), rhodium (Rh) and osmium (Os).

With reference to FIG. 1, the inner tubular body 110 of the first embodiment includes an inner tube 110a and an outer tube 110b, they are both provided to accommodate the electrolyte E. The reference electrode component 120 is placed in the inner tube 110a, and the inner tube 110a is placed in the outer tube 110b. The ionic conductive component 130 of the first embodiment includes an inner ionic conductor 130a and an outer ionic conductor 130b, the inner ionic conductor 130a is disposed through the inner tube 110a, and the outer ionic conductor 130b is disposed through and protrudes from the outer tube 110b so the first electrode assembly 100 of the first embodiment is known as a dual salt bridge design.

The electrolyte E is a liquid or gel-like electrolyte of potassium chloride (KCl), sodium chloride (NaCl), hydrogen chloride (HCl), ferric chloride (FeCl₃) or ferrous chloride (FeCl₂). Preferably, the reference electrode component 120 and the ionic conductive component 130 are soaked in NaCl solution, and user can add or replace the electrolyte E in the inner tubular body 110 for different conditions.

With reference to FIG. 1, the sensing electrode A further includes a second electrode assembly 200. The second electrode assembly 200 includes an outer tubular body 210 and a working electrode component 220, both ends of the outer tubular body 210 are defined as a sensing end 211 and a conductive end 212, respectively. The working electrode component 220 is installed in the outer tubular body 210 and has an exposed end 221 exposed on the sensing end 211 of the outer tubular body 210. In this embodiment, the exposed end 221 of the working electrode component 220 protrudes from the sensing end 211 of the outer tubular body 210, consequently, it contacts an etching solution during ORP measurement.

The working electrode component 220 is made of unary metal, binary metal or ternary metal and preferably includes at least one metal material selected from the group consisting of platinum (Pt), gold (Au), palladium (Pd), silver (Ag), iridium (Ir), titanium (Ti), ruthenium (Ru), rhodium (Rh) and osmium (Os). The working electrode component 220 is a metal wire or metal stick having a diameter between 0.01 mm and 3 mm and a length between 10 mm and 150 mm.

During ORP measurement using the sensing electrode A, the sensing end 211 of the outer tubular body 210 is placed in the etching solution, for this reason, the outer tubular body 210 is preferably made of polymer material having excellent corrosion resistance, such as high density polyethylene (HDPE), low density polyethylene (LDPE), linear low density polyethylene (LLDPE), polypropylene (PP), polyvinyl chloride (PVC), polyvinylidene difluoride (PVDF), polyetheretherketon (PEEK), polytetrafluoroethylene (PTFE), polyoxymethylene (POM), phenol-formaldehyde resin (PF), polycarbonate (PC), acrylonitrile-butadiene-styrene (ABS), Nylon 66, poly(methyl methacrylate) (PMMA) or polyphenylene sulfide (PPS). The outer tubular body 210 is protected from the corrosion in the etching solution so as to prevent infiltration of the etching solution into the sensing electrode A.

With reference to FIG. 1, the sensing electrode A further includes a lid 300 and a first sealing component 400 that is disposed in the outer tubular body 210. The first electrode assembly 100 is placed into the outer tubular body 210 of the second electrode assembly 200 to allow the first sealing component 400 to be located between the sensing end 111 of the inner tubular body 110 and the sensing end 211 of the outer tubular body 210. There is a first through hole 213 located on the sensing end 211 of the outer tubular body 210, and the ionic conductive component 130 protruding from the inner tubular body 110 is inserted into the first sealing component 400 and visible from the first through hole 213. Then, the lid 300 is provided to cover the conductive end 112 of the inner tubular body 110 so as to seal the inner tubular body 110. The lid 300 can protect the reference electrode component 120 in the inner tubular body 110 and prevent leakage of the electrolyte E from the conductive end 112 of the inner tubular body 110. Besides, after removing the lid 300 from the inner tubular body 110, user can replace, repair or clean the reference electrode component 120, or replace the electrolyte E in the inner tubular body 110, or add additional electrolyte E into the inner tubular body 110.

With reference to FIG. 1, the conductive end 112 of the inner tubular body 110 installed in the outer tubular body 210 protrudes from the conductive end 212 of the outer tubular body 210, and the inner tubular body 110 is pressed down by the lid 300 when fixing the lid 300 on the conductive end 112 of the inner tubular body 110 such that the first sealing component 400 is clamped between the sensing end 111 of the inner tubular body 110 and the sensing end 211 of the outer tubular body 210 to seal the first through hole 213 on the outer tubular body 210. The first sealing component 400 is provided to prevent the etching solution from infiltrating into the outer tubular body 210 via the first through hole 213, in addition, the first sealing component 400 is also provided to prevent the electrolyte E from running out of the inner tubular body 110.

In this embodiment, there is a recess 310 having an internal thread (not shown) in the lid 300, the internal thread is engaged with an external thread (not shown) on the conductive end 112 of the inner tubular body 110 so as to fasten the lid 300 to the conductive end 112 of the inner tubular body 110.

The outer ionic conductor 130b protruding from the outer tube 110b is inserted into the first sealing component 400 and the first through hole 213 of the outer tubular body 210 as the first electrode assembly 100 is installed in the outer tubular body 210, and the outer ionic conductor 130b is visible from the first through hole 213. Consequently, the outer ionic conductor 130b contacts the etching solution during ORP measurement. In this embodiment, the outer ionic conductor 130b protrudes from the first through hole 213. With reference to FIG. 1, the outer tubular body 210 preferably further includes a second through hole 214 which is located on the conductive end 212 of the outer tubular body 210, and the sensing electrode A preferably further includes a second sealing component 500. The second sealing component 500 is installed in the second through hole 214 and clamped between the conductive end 112 of the inner tubular body 110 and the conductive end 212 of the outer tubular body 210 as the inner tubular body 110 is inserted into the second sealing component 500 to be placed in the outer tubular body 210. The second sealing component 500 is provided to prevent leakage of the electrolyte E and prevent infiltration of the etching solution into the sensing electrode A via the second through hole 214.

With reference to FIG. 1, preferably, a third through hole 215 located outside the first through hole 213 is further provided on the sensing end 211 of the outer tubular body 210, and the sensing electrode A further includes a third sealing component 600 installed in the third through hole 215. The exposed end 221 of the working electrode component 220 is inserted into the third sealing component 600 and visible from the third through hole 215. In this embodiment, the exposed end 221 of the working electrode component 220 protrudes from the third through hole 215. The third sealing component 600 is used to seal the third through hole 215 so that the etching solution is unable to run into the sensing electrode A via the third through hole 215. In this embodiment, the first sealing component 400, the second sealing component 500 and the third sealing component 600 are O-rings made of corrosion resist material so corrosion of the sealing components by the etching solution is inhibited and the outer tubular body 210 is sealed against the infiltration of the etching solution. The first sealing component 400, the second sealing component 500 and the third sealing component 600 may be made of sealant or other sealing material in other embodiment.

With reference to FIG. 1, the sensing electrode A further includes a first electric conductor 700 installed on the lid 300 for electrical connection to an external electronic device. The external electronic device may be effective voltmeter or potentiostat. When coving the lid 300 on the conductive end 112 of the inner tubular body 110, the reference electrode component 120 is electrically connected to the first electric conductor 700. Preferably, the first electrode assembly 100 further includes a first connection port 140 located on the conductive end 112 of the inner tubular body 110, and the first electric conductor 700 located in the recess 310 of the lid 300 contacts the first connection port 140 when the lid 300 is fastened to the conductive end 112 of the inner tubular body 110 such that the reference electrode component 120 is electrically connected to the first electric conductor 700 via the first connection port 140. In this embodiment, the reference electrode component 120 is electrically connected to effective voltmeter or potentiostat through the first connection port 140 and the first electric conductor 700.

With reference to FIG. 1, the second electrode assembly 200 further includes a second connection port 230 installed on the conductive end 212 of the outer tubular body 210, and the working electrode component 220 is electrically connected to effective voltmeter or potentiostat through the second connection port 230. In this embodiment, one end of the working electrode component 220 is connected to the second connection port 230, and the other end of the working electrode component 220 is the exposed end 221 protruding from the third through hole 215 of the outer tubular body 210.

In this embodiment, the electrochemical signal generated by the reference electrode component 120 is output to the external electronic device through the first connection port 140, the first electric conductor 700 and a wire, and the electrochemical signal generated by the working electrode component 220 is output to the external electronic device through the second connection port 230 and another wire. The electrical potential difference between the electrochemical signals generated by the reference electrode component 120 and the working electrode component 220 is provided for ORP measurement of the etching solution in the external electronic device.

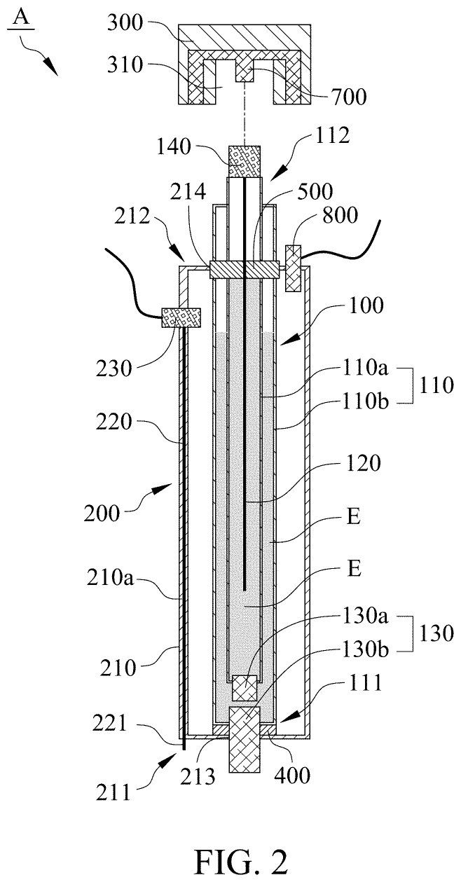

FIG. 2 shows a second embodiment of the present invention. Different to the first embodiment, the working electrode component 220 of the second embodiment is inserted into a wall 210a of the outer tubular body 210 so as to protect the working electrode component 220 from oxidation and achieve an extended service life.

With reference to FIG. 2, the sensing electrode A of the second embodiment further includes a second electric conductor 800 installed on the conductive end 212 of the outer tubular body 210. The first electric conductor 700 on the lid 300 is electrically connected to the reference electrode component 120 and the second electric conductor 800 as the lid 300 is provided to cover the conductive end 111 of the inner tubular body 110. The second electric conductor 800 is used to electrically connect to the external electronic device such that the electrochemical signal generated by the reference electrode component 120 is output to the external electronic device through the first connection port 140, the first electric conductor 700, the second electric conductor 800 and a wire. Preferably, the first electric conductor 700 and the second electric conductor 800 are spring-loaded contacts.

The first electrode assembly 100 is placed in the outer tubular body 210 so the reference electrode component 120 is separated from the etching solution to have a longer service life and a better measurement accuracy. Moreover, the first sealing component 400 located between the inner tubular body 110 and the outer tubular body 210 is provided to inhibit infiltration of the etching solution into the outer tubular body 210 and leakage of the electrolyte E so as to protect the reference electrode component 120 and the working electrode component 220 and improve the stability and service life of the sensing electrode A.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A sensing electrode comprising:
a first electrode assembly including an inner tubular body configured to accommodate an electrolyte, a reference electrode component installed in the inner tubular body and an ionic conductive component disposed through and protruding from a sensing end of the inner tubular body;
a second electrode assembly including an outer tubular body and a working electrode component installed in the outer tubular body, an exposed end of the working electrode component is exposed on a sensing end of the outer tubular body, the first electrode assembly is installed in the outer tubular body, and there is a first through hole located on the sensing end of the outer tubular body;
a first sealing component located between the sensing ends of the inner tubular body and the outer tubular body, wherein the ionic conductive component is inserted into the first sealing component and visible from the first through hole; and
a lid configured to cover a conductive end of the inner tubular body.

2. The sensing electrode in accordance with claim 1, wherein the conductive end of the inner tubular body protrudes from a conductive end of the outer tubular body, the lid is configured to be fastened to the conductive end of the inner tubular body such that the first sealing component is clamped between the sensing ends of the inner tubular body and the outer tubular body.

3. The sensing electrode in accordance with claim 2, wherein the lid includes a recess and an internal thread located in the recess, the inner tubular body includes an external thread on the conductive end, and the internal and external threads are engaged with each other.

4. The sensing electrode in accordance with claim 1 further comprising a first electric conductor, wherein the first electric conductor is installed on the lid and configured to electrically connect to an external electronic device, and the reference electrode component is electrically connected to the first electric conductor when the lid is configured to cover the conductive end of inner tubular body.

5. The sensing electrode in accordance with claim 4, wherein the first electrode assembly further includes a first connection port installed on the conductive end of the inner tubular body, the reference electrode component is electrically connected to the first electric conductor through the first connection port.

6. The sensing electrode in accordance with claim 1 further comprising a first electric conductor and a second electric conductor, wherein the first electric conductor is installed on the lid, the second electric conductor is installed on the conductive end of the outer tubular body and configured to electrically connect to an external electronic device, the first electric conductor is electrically connected to the reference electrode component and the second electric conductor when the lid is configured to cover the conductive end of the inner tubular body.

7. The sensing electrode in accordance with claim 6, wherein the first and second electric conductors are spring-loaded contacts.

8. The sensing electrode in accordance with claim 1, wherein the inner tubular body includes an inner tube and an outer tube that are configured to accommodate the electrolyte, the reference electrode component is installed in the inner tube that is installed in the outer tube, the ionic conductive component includes an inner ionic conductor and an outer ionic conductor, the inner ionic conductor is disposed through the inner tube, the outer ionic conductor is disposed through the outer tube, inserted into the first sealing component and the first through hole of the outer tubular body and visible from the first through hole.

9. The sensing electrode in accordance with claim 1, wherein the second electrode assembly further includes a second connection port installed on the conductive end of the outer tubular body, the working electrode component is electrically connected to an external electronic device through the second connection port.

10. The sensing electrode in accordance with claim 1, wherein the working electrode component is inserted into a wall of the outer tubular body.

11. The sensing electrode in accordance with claim 1 further comprising a second sealing component, wherein the second sealing component is installed in a second through hole located on a conductive end of the outer tubular body, the inner tubular body is inserted into the second sealing component such that the second sealing component is clamped between the conductive ends of the inner tubular body and the outer tubular body.

12. The sensing electrode in accordance with claim 1 further comprising a third sealing component, wherein the third sealing component is installed in a third through hole located on the sensing end of the outer tubular body, the exposed end of the working electrode component is inserted into the third sealing component and visible from the third through hole.

13. The sensing electrode in accordance with claim 1, wherein the reference electrode component is a silver/silver chloride electrode, a saturated calomel electrode or a standard hydrogen electrode.

14. The sensing electrode in accordance with claim 1, wherein the working electrode component is made of at least one metal material selected from the group consisting of platinum (Pt), gold (Au), palladium (Pd), silver (Ag), iridium (Ir), titanium (Ti), ruthenium (Ru), rhodium (Rh) and osmium (Os).

15. The sensing electrode in accordance with claim 1, wherein the ionic conductive component is made of a porous ceramic material.

16. The sensing electrode in accordance with claim 15, wherein the ionic conductive component is made of a porous silicon oxide or a porous metal oxide that includes at least one metal material selected from the group consisting of platinum (Pt), gold (Au), palladium (Pd), silver (Ag), iridium (Ir), titanium (Ti), ruthenium (Ru), rhodium (Rh) and osmium (Os).

17. The sensing electrode in accordance with claim 1, wherein the outer tubular body is made of high density polyethylene (HDPE), low density polyethylene (LDPE), linear low density polyethylene (LLDPE), polypropylene (PP), polyvinyl chloride (PVC), polyvinylidene difluoride (PVDF), polyetheretherketon (PEEK), polytetrafluoroethylene (PTFE), polyoxymethylene (POM), phenol-formaldehyde resin (PF), polycarbonate (PC), acrylonitrile-butadiene-styrene (ABS), Nylon 66, poly(methyl methacrylate) (PMMA) or polyphenylene sulfide (PPS).

18. The sensing electrode in accordance with claim 1, wherein the electrolyte is a liquid or gel-like electrolyte of potassium chloride (KCl), sodium chloride (NaCl), hydrogen chloride (HCl), ferric chloride (FeCl₃) or ferrous chloride (FeCl₂).
